(19) United States
(12) Patent Application Publication
(10) Pub. No.: US 2011/0088928 A1
(43) Pub. Date: Apr. 21, 2011

(54) HEAT DISSIPATING SUBSTRATE

(76) Inventors: Chang Hyun LIM, Seoul (KR); Seog Moon Choi, Seoul (KR); Tae Hoon Kim, Gyunggi-do (KR); Young Ki Lee, Gyunggi-do (KR); Hye Sook Shin, Gyunggi-do (KR); Young Ho Sohn, Gyunggi-do (KR)

(21) Appl. No.: 12/631,640

(22) Filed: Dec. 4, 2009

(30) Foreign Application Priority Data
Oct. 19, 2009 (KR) 10-2009-0099304

(51) Int. Cl. H05K 7/20

(52) U.S. Cl. 174/252

(57) ABSTRACT

Disclosed is a heat dissipating substrate, which includes a metal plate, an insulating film formed on the surface of the metal plate, a circuit pattern formed on the insulating film, and a first via formed to pass through at least a part of the metal plate so that the metal plate and the circuit pattern are electrically connected to each other, and also which exhibits superior heat dissipation effects and enables the configuration of a circuit board to be simple due to no need to additionally provide a ground layer and a power layer.

### CROSS REFERENCE TO RELATED APPLICATION

This application claims the benefit of Korean Patent Application No. 10-2009-0099304, filed Oct. 19, 2009, entitled “Heat-Radiating Substrate”, which is hereby incorporated by reference in its entirety into this application.

### BACKGROUND OF THE INVENTION

1. Technical Field

The present invention relates to a heat dissipating substrate.

2. Description of the Related Art

With the recent trend of an increasing use of electronic apparatuses requiring complicated functions, a variety of electronic components are mounted on a single substrate. The respective electronic components are typically powered via a wiring pattern on the surface of the substrate. In this case, because of a large number of electronic components being mounted on the substrate, the number of wiring patterns supplying power is increased, thereby increasing the complexity of wiring patterns and the loss of power.

Also, in order to prevent a variety of electronic components mounted on a circuit board from damage due to static electricity or leakage current, and, in the case of an RF device, in order to eliminate interference therefrom, a circuit board is generally provided with a ground structure.

Thereby, the complexity of a circuit structure is increased on the limited area of the substrate, undesirably causing heating problems and making it difficult to eliminate interference from the RF device.

In a conventional printed circuit board (PCB) using ground/power layers composed of a copper metal layer, a PM (power module) or PA (power amplifier) should essentially have grounding performance in order to accomplish PDN (Power Delivery Network) and eliminate interference, as well as heat dissipation properties.

To this end, the conventional PCB is configured such that additional parts are further provided or the size and thickness of the circuit board are increased. Typically, a PCB has a multilayer structure in which a ground layer for performing grounding of the substrate and a power layer for applying predetermined power to the substrate are additionally formed.

Such a PCB is disadvantageous because it includes not only a layer for mounting an electronic component but also additional layers for grounding and power functions. Also, in order to minimize resistance when power is supplied, a metal layer is formed of copper, but problems of its size limit and design restrictions may unavoidably occur attributable to a general wiring pattern. Thereby, the position of the electronic component which needs a power connection is also limited. In the case of a heat dissipating substrate which uses a metal material, it is difficult to form a ground layer and a power layer, negatively affecting heat dissipation properties.

In addition, another conventional PCB is provided in the form of a package device in which a shielding structure and an insulating layer are additionally formed under the substrate to eliminate electromagnetic wave interference. Such a PCB is configured such that the substrate and the shielding structure are connected by means of a through hole. Furthermore, an additional device for dissipating heat is provided under the shielding structure and the insulating layer. This PCB is problematic because a structure for shielding electromagnetic waves and a heat dissipating structure should be additionally provided in addition to the substrate for supporting the device. Also, the PCB in the form of a package device has problems related to process complexity and high material cost.

### SUMMARY OF THE INVENTION

Accordingly, the present invention has been made keeping in mind the problems encountered in the related art and the present invention is intended to provide a heat dissipating substrate, in which a metal plate is used as a substrate thus solving heat dissipation problems, and simultaneously, the metal plate is used as a ground layer and a power layer thus decreasing loss of power, and reducing the surface area of the substrate to thereby increase the degree of freedom with which the substrate may be designed.

An aspect of the present invention provides a heat dissipating substrate, including a metal plate, an insulating film formed on the surface of the metal plate, a circuit pattern formed on the insulating film, and a first via formed to pass through at least a part of the metal plate so that the metal plate and the circuit pattern are electrically connected to each other.

In this aspect, the insulating film may be formed by anodizing the metal plate.

In this aspect, the metal plate may be formed of a material including aluminum or an aluminum alloy, and the insulating film may be an Al₂O₃ layer formed by anodizing the metal plate.

In this aspect, the first via may be formed in the metal plate, so that the circuit pattern formed on one surface of the metal plate is connected to the circuit pattern formed on the other surface of the metal plate.

In this aspect, the metal plate may include a through hole having the insulating film formed on an inner wall thereof, and may further include a second via formed in the through hole, so that the circuit pattern formed on one surface of the metal plate is connected to the circuit pattern formed on the other surface of the metal plate.

In this aspect, the metal plate may be electrically separated into a plurality of regions by an insulating member.

In this aspect, the insulating member may be formed by subjecting the metal plate to volume anodizing treatment.

In this aspect, the metal plate may be formed of a material including aluminum or an aluminum alloy, and the insulating member may be an Al₂O₃ layer formed by subjecting the metal plate to volume anodizing treatment.

In this aspect, the metal plate separated by the insulating member may include a power region and a ground region, and the power region may have two or more separated regions to which different magnitudes of power are applied.

In this aspect, the metal plate separated by the insulating member may include a power region and a ground region, and the ground region may have two or more separated regions.

Another aspect of the present invention provides a heat dissipating substrate, including a first base substrate and a second base substrate each including a metal plate having an insulating film formed on a surface thereof and a first via formed to pass through at least a part of the metal plate so that circuit patterns formed on the metal plate and the insulating film are electrically connected to each other, an insulating layer formed between the first base substrate and the second base substrate, and a connection via formed in the insulating layer, so that circuit patterns formed on the first base substrate and the second base substrate are connected to each other, wherein the first base substrate is connected to a ground terminal, and the second base substrate is connected to a power terminal.

In this aspect, the insulating film may be formed by anodizing the metal plate.

In this aspect, the metal plate may be formed of a material including aluminum or an aluminum alloy, and the insulating film may be an Al₂O₃ layer formed by anodizing the metal plate.

In this aspect, the first via may be formed in the metal plate, so that the circuit patterns formed on both surfaces of the metal plate are connected to each other.

In this aspect, the metal plate may include a through hole having the insulating film formed on an inner wall thereof, and may further include a second via formed in the through hole, so that the circuit patterns formed on both surfaces of the metal plate are connected to each other.

In this aspect, the metal plate may be electrically separated into a plurality of regions by an insulating member.

In this aspect, the insulating member may be formed by subjecting the metal plate to volume anodizing treatment.

In this aspect, the metal plate may be formed of a material including aluminum or an aluminum alloy, and the insulating member may be an Al₂O₃ layer formed by subjecting the metal plate to volume anodizing treatment.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a heat dissipating substrate according to a first embodiment of the present invention;

FIG. 2 is a top plan view showing a heat dissipating substrate according to a second embodiment of the present invention;

FIG. 3 is a cross-sectional view taken along the line A-A′ of FIG. 2 which shows the heat dissipating substrate according to the second embodiment;

FIG. 4 is a top plan view showing a heat dissipating substrate according to a third embodiment of the present invention;

FIG. 5 is a cross-sectional view taken along the line B-B′ of FIG. 4 which shows the heat dissipating substrate according to the third embodiment;

FIG. 6 is a cross-sectional view taken along the line C-C′ of FIG. 4 which shows the heat dissipating substrate according to the third embodiment; and

FIG. 7 is a cross-sectional view showing a heat dissipating substrate according to a fourth embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. Furthermore, descriptions of known techniques, even if they are pertinent to the present invention, are regarded as unnecessary and may be omitted in so far as they would make the characteristics of the invention unclear and render the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

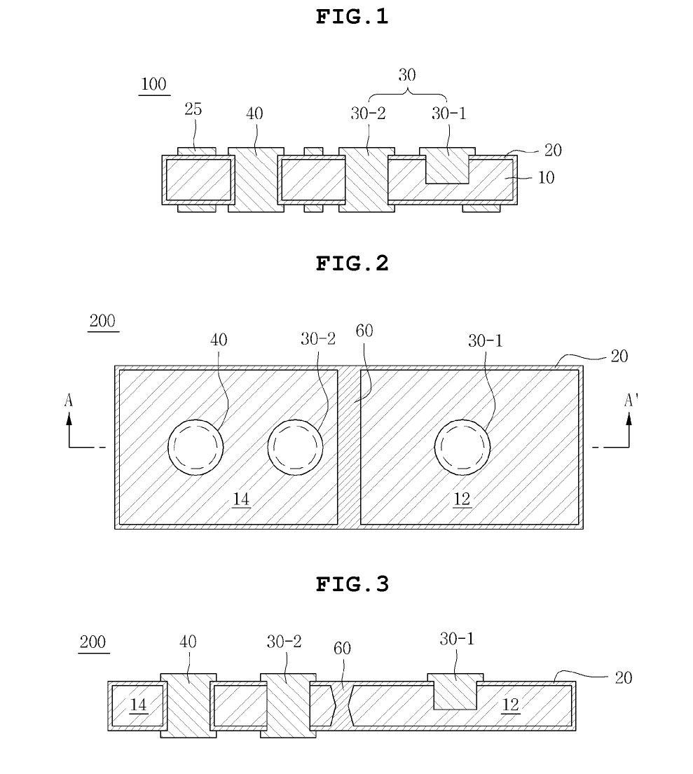

FIG. 1 is a cross-sectional view showing a heat dissipating substrate according to a first embodiment of the present invention. With reference to this drawing, the heat dissipating substrate according to the present embodiment is described below.

As shown in FIG. 1, the heat dissipating substrate 100 includes a metal plate 10, an insulating film 20 formed on the surface of the metal plate 10, a circuit pattern 25, and a first via 30 connected to the metal plate 10.

The metal plate 10 is used as a base of the heat dissipating substrate, and determines a thickness of the substrate. The metal plate 10 may be made of any metal selected from among a variety of metals, such as magnesium (Mg), titanium (Ti), hafnium (Hf), and zinc (Zn). Particularly useful is a metal plate made of aluminum or an aluminum alloy. This is because aluminum which is lightweight may reduce the total weight of the heat dissipating substrate, and also enables the formation of an insulating film made of Al₂O₃ which will be described later.

Because such a metal plate 10 has high heat transfer efficiency, it advantageously exhibits superior heat dissipation properties on a heat dissipating substrate including a heating device.

Also, the insulating film 20 is formed on the surface of the metal plate 10. Because the metal plate 10 is electrically conductive, a circuit pattern is not directly formed on the metal plate 10, but the insulating film 20 is formed on the metal plate 10 and then the circuit pattern 25 is formed on the insulating film 20. The insulating film may be made of a typical plastic resin.

As such, the insulating film 20 may be formed by anodizing the metal plate (anodizing treatment). When voltage is applied to an electrolytic solution in which the metal plate is used as an anode, the surface of the metal is oxidized by oxygen generated at the anode, thus forming a metal oxide film.

Such an insulating film 20 may be made of Al₂O₃ formed by anodizing for example an aluminum plate or an aluminum alloy plate. Furthermore, Al₂O₃ is formed thin, and thus the total thickness of the heat dissipating substrate may be reduced. The anodizing treatment process for anodizing the aluminum plate is known in the art, and thus a detailed description thereof is omitted.

The circuit pattern 25 formed on the insulating film 20 supplies power to the electronic component mounted on the heat dissipating substrate, and also transmits an electrical signal between electronic components.

The first via 30 is formed to pass through at least a part of the metal plate 10 so that the metal plate 10 and the circuit pattern 25 are electrically connected to each other. The first via 30 may result from forming a plating layer in a via hole or filling a via hole with solder paste.

As such, the first via 30 may have a shape of a blind via 30-1. The blind via 30-1 may have one end connected to the metal plate 10, and the other end exposed to the insulating film 20 and thus connected to the circuit pattern 25 formed on the insulating film 20.

In addition, the first via 30 may have a shape of a through via 30-2. The through via 30-2 is formed in the metal plate 10, and the upper and lower sides of the first via 30 are connected to the circuit pattern 25 formed on the insulating film 20. Thus, the through via 30-2 is connected to the metal plate 10 at the body thereof passing through the metal plate 10.

The first via 30 functions as follows. When a power terminal for applying external power is connected to the metal plate 10, the metal plate 10 plays a role as a power layer. In addition, when a ground terminal is connected to the metal plate 10, the metal plate 10 plays a role as a ground layer. Hence, when the metal plate 10 functions as the power layer, the first via 30 acts as a power via, so that the external power is delivered to the circuit pattern 25 and then to the electronic component mounted on the heat dissipating substrate 100.

On the other hand, when the metal plate 10 plays a role as the ground layer, the first via 30 functions as a ground via. The electronic component mounted on the heat dissipating substrate is connected to the ground layer by means of the ground via, thus reducing defective rate due to static electricity.

A general PCB is problematic because an additional circuit pattern acting as a power layer or a ground layer is formed and thus the thickness of the PCB is increased and the circuit pattern becomes complicated. However, the heat dissipating substrate 100 according to the present embodiment is advantageous because the thickness of the substrate is reduced and the design of the circuit pattern becomes simple.

The heat dissipating substrate 100 according to the present embodiment is configured such that the metal plate 10 includes a through hole having an insulating film formed on the inner wall thereof, and further includes a second via 40 formed in the through hole so as to electrically connect circuit patterns 25 formed on both surfaces of the metal plate to each other.

The second via 40 may result from forming the through hole in the metal plate 10, forming the insulating film on the inner surface of the through hole, and filling the through hole with a conductive material (or forming a plating layer made of a conductive material in the through hole). The second via 40 is not connected to the metal plate 10, unlike the first via 30-2, and thus functions to transmit an electrical signal to the circuit patterns 25 formed on both surfaces of the heat dissipating substrate 100 and to transmit a signal between the electronic components mounted on both surfaces of the substrate.

As such, the insulating film formed on the inner wall of the through hole may be formed through anodizing treatment. For example, a through hole is formed in an aluminum plate, and the aluminum plate is anodized, thus obtaining the insulating film formed of Al₂O₃.

FIG. 2 is a top plan view showing a heat dissipating substrate 200 according to a second embodiment of the present invention, and FIG. 3 is a cross-sectional view taken along the line A-A′ of FIG. 2 showing the heat dissipating substrate 200. With reference to these drawings, the heat dissipating substrate according to the present embodiment is described below. The detailed description of the elements of this heat dissipating substrate, which are the same as those of the heat dissipating substrate of FIG. 1, is omitted.

By way of a clear description of the heat dissipating substrate 200, an insulating film 20 formed on an upper surface of a metal plate 10 is shown as being omitted in FIG. 2, and a circuit pattern formed on the insulating film 20 is also omitted in FIGS. 2 and 3.

As shown in FIGS. 2 and 3, the heat dissipating substrate 200 according to the present embodiment includes a metal plate 10, an insulating film 20 formed on the surface of the metal plate 10, a circuit pattern formed on the insulating film 20, and a first via 30 formed to pass through at least a part of the metal plate 10 so as to be connected to the circuit pattern formed on the surface of the insulating film 20, and the metal plate 10 is electrically separated into a plurality of regions by an insulating member 60.

As such, the insulating member 60 may be made of an insulating material such as a plastic resin in order to electrically separate the metal plate 10.

Alternatively, the insulating member 60 may be formed by subjecting the metal plate 10 to volume anodizing (or bulk anodizing) treatment. For example, when anodizing treatment is performed in a direction of thickness of an aluminum plate or an aluminum alloy plate, an insulating member 60 made of Al₂O₃ corresponding to the thickness of the plate may be formed.

As shown in FIG. 2, the metal plate 10 may be separated into two regions by a single insulating member 60. One of the two regions may be a ground region 12 and the other thereof may be a power region 14. When a single metal plate 10 is spatially separated in this way, both the ground region 12 and the power region 14 may be formed on the same plane, so that the circuit pattern formed on the heat dissipating substrate 20 becomes simple and the manufacturing process of the heating dissipating substrate 200 is simplified.

Also, as shown in FIG. 3, the ground region 12 and the power region 14 each include the first via 30. The first via 30 may be either the blind via 30-1 or the through via 30-2 as mentioned above. Although the formation of a single first via 30 in each of the ground region 12 and the power region 14 is illustrated in FIG. 3, the number of first vias may be changed.

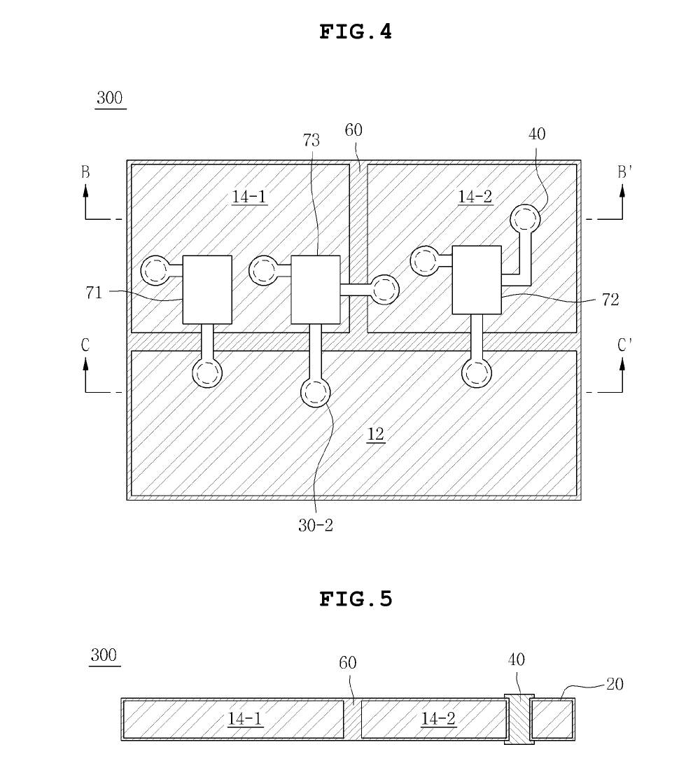

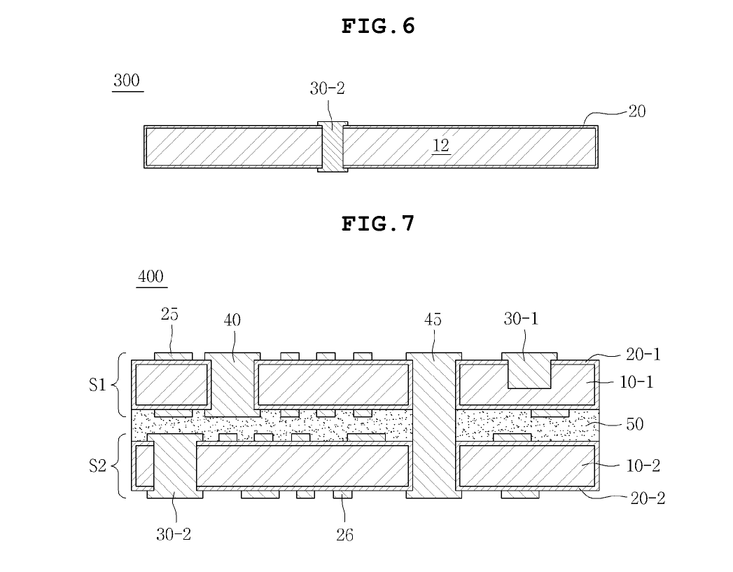

FIG. 4 is a top plan view showing a heat dissipating substrate 300 according to a third embodiment of the present invention, and FIGS. 5 and 6 are cross-sectional views taken along the line B-B′ and the line C-C′ of FIG. 4, respectively. With reference to these drawings, the heat dissipating substrate 300 according to the present embodiment is described below. The detailed description of the elements of this heat dissipating substrate, which are the same as those of the heat dissipating substrate 200 of FIGS. 2 and 3, is omitted.

The heat dissipating substrate 300 of FIG. 4 is configured such that a metal plate 10 is separated into a single ground region 12 and two power regions 14 by an insulating member 60. By way of a clear description of the heat dissipating substrate 300, an insulating film 20 formed on the upper surface of a metal plate 10 is shown as being omitted in FIG. 4.

Herein, the magnitude of power applied to a first power region 14-1 and a second power region 14-2 may vary. For example, 1.8 V and 1.2 V may be applied to the first power region 14-1 and the second power region 14-2, respectively.

As such, external power is applied to the first power region 14-1, and the second power region 14-2 is supplied with power delivered from the first power region 14-1. The magnitude of voltage delivered from the first power region 14-1 is reduced by a regulator 73 mounted on the heat dissipating substrate, and then the resulting voltage is applied to the second power region 14-2.

As shown in FIG. 4, a plurality of electronic components 71, 72, 73 may be mounted on the heat dissipating substrate, and such electronic components may be supplied with different magnitudes of power. A single power region is separated into a plurality of power regions to which different magnitudes of power are applied, and the electronic components adapted for the magnitudes of power are linked to the respective power regions, thereby reducing the amount of lost power.

In addition, the ground region 12 may also be separated into two or more regions by the insulating member 60. One of the regions is used as a ground region of a digital electronic component among the plurality of electronic components mounted on the heat dissipating substrate, and the other may be used as a ground region of an analog electronic component among them. Thus, grounding performance of the heat dissipating substrate 300 is improved.

Also, as shown in FIG. 5, the power region 14 may include a second via 40 in order to connect circuit patterns formed on both surfaces of the metal plate 10 to each other. As shown in FIG. 6, a first via 30-2 is located in the ground region 12 so that the circuit pattern and the metal plate 10 are connected to each other.

FIG. 4 shows the metal plate which is separated into a single ground region and two power regions. The number of ground and power regions may be increased depending on the shape of the insulating member 60.

FIG. 7 is a cross-sectional view showing a heat dissipating substrate 400 according to a fourth embodiment of the present invention. With reference to this drawing, the heat dissipating substrate 400 according to the present embodiment is described below. The detailed description of the elements of this heat dissipating substrate, which are the same as those of the heat dissipating substrates of FIGS. 1 to 6, is omitted.

As shown in FIG. 7, the heat dissipating substrate 400 according to the present embodiment may have a multilayer structure. The heat dissipating substrate 400 includes a first base substrate S1 and a second base substrate S2 each including a metal plate 10 on which an insulating film 20 is formed, and a first via 30 formed in the metal plate 10. The first base substrate S1 and the second base substrate S2 are respectively connected to a ground terminal and a power terminal and thus used as a ground layer and a power layer.

The first metal plate 10-1 for the ground layer and the second metal plate 10-2 for the power layer may be provided in the form of a multilayer with an additional insulating layer 50 being disposed therebetween.

As such, the heat dissipating substrate 400 further includes a connection via 45 for electrically connecting a circuit pattern 25 formed on the first metal plate 10-1 to a circuit pattern 26 formed on the second metal plate 10-2. The connection via 45 is similar to the structure of the second via 40 as shown in FIG. 1, and is not electrically connected to the first metal plate 10-1 and the second metal plate 10-2.

The connection via 45 functions to electrically connect one or more among circuit patterns 25 formed on both surfaces of the first metal plate 10-1 to one or more among circuit patterns 26 formed on both surfaces of the second metal plate 10-2.

The first base substrate S1 and the second base substrate S2 may include the second via 40 as mentioned above.

The first metal plate 10-1 and the second metal plate 10-2 of the first base substrate S1 and the second base substrate S2 may be separated into a plurality of regions by an insulating member (not shown).

As such, the first metal plate 10-1 of the first base substrate S1 which forms the ground layer is divided into a plurality of ground regions. As aforementioned with reference to FIG. 4, the ground regions may be separately used depending on the types of mounted electronic component.

The second metal plate 10-2 of the second base substrate S2 which forms the power layer is divided into a plurality of power regions, and the magnitude of power applied to the power regions may vary as aforementioned with reference to FIG. 4.

The heat dissipating substrate 400 of FIG. 7 includes four circuit layers. However, the insulating layer 50 between the first metal plate 10-1 and the second metal plate 10-2 may be provided in the form of a monolayer or a multilayer including insulating and metal layers, which is apparent to those skilled in the art and the detailed description of which is omitted.

As described hereinbefore, the present invention provides a heat dissipating substrate. According to the present invention, the heat dissipating substrate includes a metal plate which mounts an electronic component, thus exhibiting outstanding heat dissipation effects.

Also, according to the present invention, because there is no need to additionally provide a ground layer and a power layer, a circuit board has a simple configuration, and can be freely designed, thus simplifying the manufacturing process.

Also, according to the present invention, the metal plate can be separated into a plurality of regions through volume anodizing treatment, thus making it possible to supply different magnitudes of power to thereby reduce loss of power.

Although the embodiments of the present invention regarding the heat dissipating substrate have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A heat dissipating substrate, comprising:
a metal plate;
an insulating film formed on a surface of the metal plate;
a circuit pattern formed on the insulating film; and
a first via formed to pass through at least a part of the metal plate so that the metal plate and the circuit pattern are electrically connected to each other.

2. The heat dissipating substrate as set forth in claim 1, wherein the insulating film is formed by anodizing the metal plate.

3. The heat dissipating substrate as set forth in claim 1, wherein the metal plate is formed of a material comprising aluminum or an aluminum alloy, and the insulating film is an Al₂O₃ layer formed by anodizing the metal plate.

4. The heat dissipating substrate as set forth in claim 1, wherein the first via is formed in the metal plate, so that the circuit pattern formed on one surface of the metal plate is connected to the circuit pattern formed on the other surface of the metal plate.

5. The heat dissipating substrate as set forth in claim 1, wherein the metal plate includes a through hole having the insulating film formed on an inner wall thereof, and further includes a second via formed in the through hole, so that the circuit pattern formed on one surface of the metal plate is connected to the circuit pattern formed on the other surface of the metal plate.

6. The heat dissipating substrate as set forth in claim 1, wherein the metal plate is electrically separated into a plurality of regions by an insulating member.

7. The heat dissipating substrate as set forth in claim 6, wherein the insulating member is formed by subjecting the metal plate to volume anodizing treatment.

8. The heat dissipating substrate as set forth in claim 7, wherein the metal plate is formed of a material comprising aluminum or an aluminum alloy, and the insulating member is an Al₂O₃ layer formed by subjecting the metal plate to volume anodizing treatment.

9. The heat dissipating substrate as set forth in claim 6, wherein the metal plate separated by the insulating member includes a power region and a ground region, and the power region comprises two or more separated regions to which different magnitudes of power are applied.

10. The heat dissipating substrate as set forth in claim 6, wherein the metal plate separated by the insulating member includes a power region and a ground region, and the ground region comprises two or more separated regions.

11. A heat dissipating substrate, comprising:
a first base substrate and a second base substrate each comprising a metal plate having an insulating film formed on a surface thereof, and a first via formed to pass through at least a part of the metal plate so that circuit patterns formed on the metal plate and the insulating film are electrically connected to each other;
an insulating layer formed between the first base substrate and the second base substrate; and
a connection via formed in the insulating layer, so that circuit patterns formed on the first base substrate and the second base substrate are connected to each other,
wherein the first base substrate is connected to a ground terminal, and the second base substrate is connected to a power terminal.

12. The heat dissipating substrate as set forth in claim 11, wherein the insulating film is formed by anodizing the metal plate.

13. The heat dissipating substrate as set forth in claim 11, wherein the metal plate is formed of a material comprising aluminum or an aluminum alloy, and the insulating film is an Al₂O₃ layer formed by anodizing the metal plate.

14. The heat dissipating substrate as set forth in claim 11, wherein the first via is formed in the metal plate, so that the circuit patterns formed on both surfaces of the metal plate are connected to each other.

15. The heat dissipating substrate as set forth in claim 11, wherein the metal plate includes a through hole having the insulating film formed on an inner wall thereof, and further includes a second via formed in the through hole, so that the circuit patterns formed on both surfaces of the metal plate are connected to each other.

16. The heat dissipating substrate as set forth in claim 11, wherein the metal plate is electrically separated into a plurality of regions by an insulating member.

17. The heat dissipating substrate as set forth in claim 16, wherein the insulating member is formed by subjecting the metal plate to volume anodizing treatment.

18. The heat dissipating substrate as set forth in claim 16, wherein the metal plate is formed of a material comprising aluminum or an aluminum alloy, and the insulating member is an Al₂O₃ layer formed by subjecting the metal plate to volume anodizing treatment.
